(19) United States
(12) Patent Application Publication
(10) Pub. No.: US 2025/0316501 A1
(43) Pub. Date: Oct. 9, 2025

(54) METHOD FOR TREATING TWO SUBSTRATES AND SEMICONDUCTOR APPARATUS FOR PERFORMING THE TREATMENT

(71) Applicant: TAIWAN SEMICONDUCTOR MANUFACTURING COMPANY, LTD., Hsinchu (TW)

(72) Inventors: Hau-Yi HSIAO, Hsinchu (TW); Kuo Liang LU, Hsinchu (TW); Kuo-Ming WU, Hsinchu (TW); Sheng-Chau CHEN, Hsinchu (TW); Cheng-Yuan TSAI, Hsinchu (TW); Chung-Yi YU, Hsinchu (TW); Ru-Liang LEE, Hsinchu (TW)

(73) Assignee: TAIWAN SEMICONDUCTOR MANUFACTURING COMPANY, LTD., Hsinchu (TW)

(21) Appl. No.: 18/626,638

(22) Filed: Apr. 4, 2024

(51) Int. Cl. H01L 21/56; H01L 21/304; H01L 21/67

(52) U.S. Cl. CPC H01L 21/56; H01L 21/304; H01L 21/67126

(57) ABSTRACT

A method for treating a first substrate and a second substrate includes: bonding a first substrate with a second substrate to obtain a substrate assembly with a surrounding clearance between a first surrounding edge of the first substrate and a second surrounding edge of the second substrate, the first surrounding edge having a first region and a second region which are located in a first part and a second part of the surrounding clearance, respectively; and rotating the substrate assembly while dispensing a filling material to the surrounding clearance, in a first turn of rotation of the substrate assembly, the filling material being dispensed to the first part and the second part at a first dispensed rate and a second dispensed rate, respectively, the first dispensed rate being greater than the second dispensed rate.

### BACKGROUND

In certain fabrications of semiconductor devices, two wafers are first stacked on one another, followed by thinning of one of the wafers to reduce a thickness of the stacked wafers. To avoid peeling of the stacked wafers, especially at a clearance between two surrounding edges of the two wafers, a filling material is dispensed at the clearance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic side view illustrating a semiconductor apparatus in accordance with some embodiments, on which a substrate assembly including a first substrate and a second substrate is disposed.

FIG. 2 is a schematic top view illustrating a positional relationship between the first substrate and a dispenser valve in accordance with some embodiments.

FIG. 3 is a flow diagram illustrating a method for treating the first and second substrates in accordance with some embodiments.

FIG. 4 is a schematic top view of the substrate assembly in accordance with some embodiments, in which only the first substrate is shown and the filling material is dispensed in a periodic dispensing mode to a surrounding clearance between the two surrounding edges of the first and second substrates.

FIG. 5 is a plot showing on-off status of a dispenser valve versus time during the periodic dispensing mode in the first turn of rotation in accordance with some embodiments.

FIG. 6 is a schematic fragmentary top view of the first substrate illustrating gas release during merging and curing of the filling material in accordance with some embodiments.

FIG. 7 is a view similar to that of FIG. 4 but illustrating the result obtained after the second turn of rotation in accordance with some embodiments.

FIG. 8 are plots respectively showing on-off status of the dispenser valve versus time in the first and second turns of rotation in accordance with some embodiments.

FIG. 9 is a schematic cross-sectional view illustrating the first substrate that has peeling in accordance with some embodiments.

FIG. 10 is a schematic top view illustrating the first substrate and the filling material dispensed to the surrounding clearance in a local dispensing mode in accordance with some embodiments.

FIG. 11 is a plot showing on-off status of the dispenser valve versus time in the local dispensing mode in accordance with some embodiments.

FIG. 12 is a schematic top view illustrating the first substrate with peeling regions in accordance with some embodiments.

FIG. 13 is a plot showing an amount of the filling material per degree with reference to a starting point of 0° in accordance with some embodiments.

FIG. 14 is a schematic process flow diagram illustrating bonding of multiple wafers in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The present disclosure is directed to a method, and a semiconductor apparatus, for treating a first substrate and a second substrate. Once the first and second substrates are bonded to each other, a surrounding clearance is formed between surrounding edges of the first and second substrates. The method for treating the first and second substrates of the present disclosure involves dispensing customized amounts of a filling material to fill different parts of the surrounding clearance using the semiconductor apparatus. With use of such method, amount of voids within the surrounding clearance are greatly reduced by allowing gas, such as air, to be released out of the clearance before solidification of the filling material; and parts of the clearance that have larger volumes could be filled with greater amounts of the filling material, respectively.

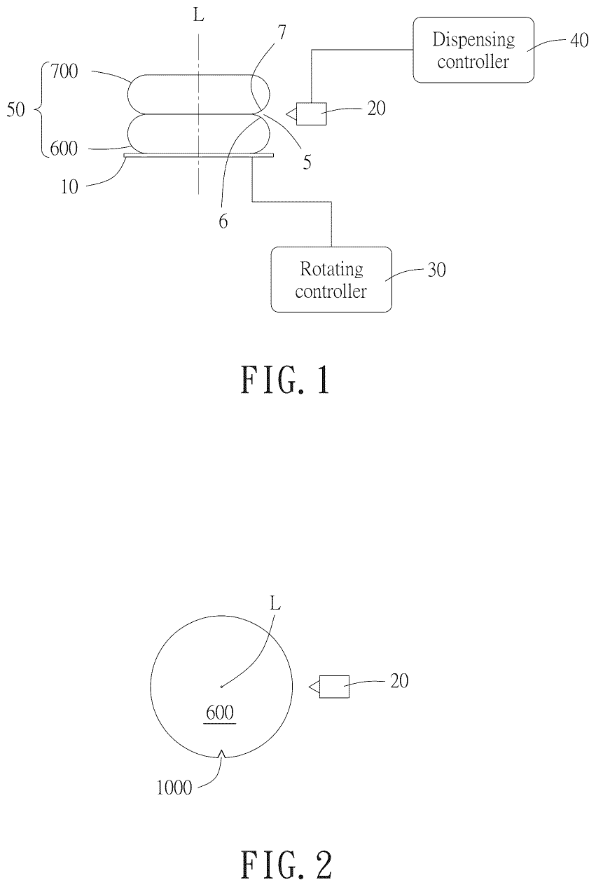

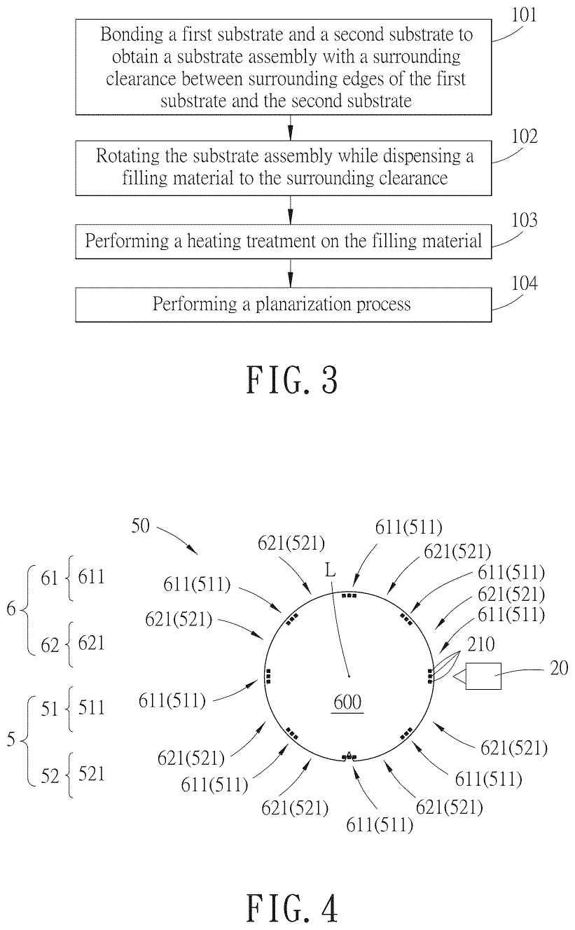

FIG. 1 is a schematic side view illustrates a semiconductor apparatus for treating a first substrate 600 and a second substrate 700 in accordance with some embodiments. FIG. 2 is a schematic top view of FIG. 1 showing merely the first substrate 600 and a dispenser valve 20 of the semiconductor apparatus in accordance with some embodiments. In some alternative embodiments, the semiconductor apparatus may further include additional features, and/or some features present in the semiconductor apparatus may be modified, replaced, or eliminated without departure from the spirit and scope of the present disclosure. FIG. 3 is a flow diagram illustrating a method for treating the first and second substrates 600, 700 in accordance with some embodiments. Additional steps can be provided before, after or during the method, and some of the steps described herein may be replaced by other steps or be eliminated.

Referring to FIGS. 1 to 3, the method begins at step 101, where the first substrate 600 and the second substrate 700 are bonded to obtain a substrate assembly 50.

Each of the first and second substrates 600, 700 may independently include, for example, but not limited to, elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. Other suitable materials for the first and second substrates 600, 700 are within the contemplated scope of the present disclosure.

Each of the first and second substrates 600, 700 may independently be a device substrate, or a carrier substrate. In some embodiments, the first substrate 600 is a device substrate and the second substrate 700 is a carrier substrate. The device substrate may include a base substrate (not shown, e.g., a semiconductor wafer) and device(s) (not shown) formed on the base substrate. For instance, the device(s) may include a front-end-of-line (FEOL) portion (e.g., a logic circuitry with transistors, a memory circuitry having memory elements, or the likes), a middle-end-of-line (MEOL) portion (e.g., contacts that are electrically connected to the FEOL portion), and a back-end-of-line (BEOL) portion (e.g., metal lines or vias). The carrier substrate may merely include a base substrate (e.g., a semiconductor wafer). Other suitable elements to be included in the device substrate and/or the carrier substrate are within the contemplated scope of the present disclosure.

As shown in FIG. 2, each of the first and second substrates 600, 700 has a notch 1000, which is configured to allow positioning and alignments of the first and second substrates 600, 700 (only the first substrate 600 is shown in FIG. 2).

Bonding of the first and second substrates 600, 700 may be performed using any techniques known in the art, so as to obtain the substrate assembly 50. Referring back to FIG. 1, in the substrate assembly 50, as the first and second substrates 600, 700 are stacked on one another, a surrounding clearance 5 is formed between the first and second substrates 600, 700. More specifically, the first substrate 600 has a first surrounding edge 6, and the second substrate 700 has a second surrounding edge 7. The surrounding clearance 5 is located between the first surrounding edge 6 of the first substrate 600 and the second surrounding edge 7 of the second substrate 700. The surrounding clearance 5 extends along and around the first and second surrounding edges 6, 7.

The first surrounding edge 6 of the first substrate 600 may have a number of regions that are angularly displaced from each other. The number of regions may be determined according to practical needs. The surrounding clearance 5 also has a number of parts that are angularly displaced from each other. The number of regions of the first surrounding edge 6 is equivalent to the number of parts of the surrounding clearance 5. Each of the regions of the first surrounding edge 6 is in position corresponding to one of the parts of the surrounding clearance 5. For instance, in some embodiments, as shown in FIG. 4, the first surrounding edge 6 of the first substrate 600 has a first region 61 and a second region 62; and the surrounding clearance 5 has a first part 51 and a second part 52. The first region 61 of the first surrounding edge 6 is located in the first part 51 of the surrounding clearance 5; the second region 62 of the first surrounding edge 6 is located in the second part 52 of the surrounding clearance 5.

The surrounding clearance 5 is to be filled with a filling material so that the filling material provides sufficient support to the first and second substrates 600, 700 in subsequent steps. In order to provide sufficient support to the first and second substrates 600, 700, such that the first or second surrounding edges 6, 7 remain intact, the filling material is dispensed in a controlled and customized manner to fill the surrounding clearance 5 using the semiconductor apparatus shown in FIG. 1. The filling material may include any suitable material that can be solidified to provide support to the first and second substrates 600, 700.

As shown in FIG. 1, the semiconductor apparatus includes a substrate holder 10, a rotating controller 30, a dispenser valve 20, and a dispensing controller 40.

The substrate holder 10 is configured to retain the substrate assembly 50 thereon. Specifically, the substrate holder 10 has a top surface on which the substrate assembly 50 is disposed thereon, and has a rotational axis (L) perpendicular to the top surface. The substrate holder 10 may be a vacuum chunk, or an electrostatic chunk, but is not limited thereto.

The dispenser valve 20 is disposed aside the substrate holder 10, and is configured to dispense the filling material to the surrounding clearance 5. When the dispenser valve 20 is switched to an on-state, the dispenser valve 20 dispenses the filling material. When the dispenser valve 20 is switched to an off-state, the dispenser valve 20 stops the dispensing of the filling material. The dispenser valve 20 is located to dispense the filling material in a radial direction with respect to the rotational axis (L) (see FIGS. 1 and 2), such that when the substrate assembly 50 is set to rotate around the rotational axis (L) and sweep through the dispenser valve 20, the dispenser valve 20 dispenses the filling material to the surrounding clearance 5 along a perimeter path around the rotational axis (L).

The rotating controller 30 is coupled to the substrate holder 10, so as to control rotation of the substrate holder 10, and thus rotation of the substrate assembly 50. The substrate holder 10 and the substrate assembly 50 may be set into rotation around the rotation axis L, and such rotation can be altered using the rotating controller 30, so that in each turn of rotation, the regions (e.g., 61, 62) of the first surrounding edge 6 can sweep through the dispenser valve 20 at different speeds, respectively.

The dispensing controller 40 is coupled to the dispenser valve 20, so as to control the dispenser valve 20 to switch between the on and off state. In each turn of rotation, the dispenser valve 20 is controlled by the dispensing controller 40 to have different on-off frequencies when the regions (e.g., 61, 62) of the first surrounding edge 6 are swept therethrough. The on-off frequency is the number of times of the dispenser valve 20 being switched between the on and off state per unit time. In the case that the dispenser valve 20 dispenses a fixed amount of the filling material for each on state and has a high on-off frequency, the dispenser valve 20 dispenses a relatively large amount of the filling material per unit time (in other words, the filling material is dispensed from the dispenser valve 20 in a relatively high rate); and in the case that the dispenser valve 20 dispenses a fixed amount of the filling material for each on state and has a low on-off frequency, the dispenser valve 20 dispenses a relatively small amount of the filling material per unit time (in other words, the filling material is dispensed from the dispenser valve 20 in a relatively low rate).

FIG. 4 is a top view of the substrate assembly 50 but omitting the second substrate 700 in accordance with some embodiments (i.e., the first substrate 600 of the substrate assembly 50 is shown). As shown in FIG. 4, the first region 61 has first sections 611 which are angularly displaced from each other, and the second region 62 has second sections 621 which are angularly displaced from each other such that the second sections 621 angularly alternate with the first sections 611. As such, the first part 51 of the surrounding clearance 5 has first areas 511 in positions corresponding to the first sections 611, and the second part 52 of the surrounding clearance 5 has second areas 521 in positions corresponding to the second sections 621.

Referring to FIGS. 1 and 3, the method proceeds to step 102, where the substrate assembly 50 is set to rotate while the filling material is dispensed to the surrounding clearance 5.

The filling material may be dispensed to different parts of the surrounding clearance 5 at different dispensed rate. In this disclosure, the term “dispensed rate” refers to an amount of the filling material to be dispensed to the surrounding clearance 5 per unit time. In each turn of rotation, the dispensed rates for the different parts of the surrounding clearance 5 may be varied, so as to regulate amounts of the filling material that are dispensed to the different parts of the surrounding clearance 5. For each of the different parts of the surrounding clearance 5, the dispensed rate may be determined by varying two factors (i) and (ii). The factor (i) is a speed of a certain region (e.g., 61 or 62) of the first substrate 600 that is swept over the dispenser valve 20 and can be varied using the rotating controller 30. The factor (ii) is the on-off frequency of the dispenser valve 20 when the certain region of the first substrate 600 is swept over the dispenser valve 20, and can be varied using the dispensing controller 40.

Please note that the different regions of the first substrate 600 (or the different parts of the surrounding clearance 5), may be identified and tracked using any suitable methods known in the art. In some embodiments, when the regions on the first surrounding edge 6 of the first substrate 600 are randomly distributed, the positions of the randomly distributed regions relative to the notch 1000 may be determined before step 101. In some other embodiments, when the regions on the first surrounding edge 6 of the first substrate 600 are regularly distributed, the portions of the regularly distributed regions relative to the notch 1000 may be determined prior to or after step 101. For instance, locations of the different regions of the first substrate 600 may be identified based on an angle between each of the different regions and a reference point, such as the notch 1000, but is not limited thereto. Furthermore, in other embodiments, volumes of the different parts of the surrounding clearance 5 may be detected. For instance, a particular part of the surrounding clearance 5 is detected to have a particularly large volume of void. Such particular part is in position corresponding to a particular region of the first substrate 600, which is identified to be, e.g., 100° away from e.g., the notch 1000. By identifying the different regions of the first substrate 600 that sweep over the dispenser valve 20, the aforementioned factors (i) and (ii) may be varied accordingly based on the conditions of the different regions identified. Please also note that one can freely determine when and where to dispense the filling material on the surrounding clearance 5 according to practical needs. In some embodiments, even when the assembly 50 starts to rotate, the dispensing of the filling material does not start until a predetermined region of the surrounding edge 6 sweeps through the dispenser valve 20. That is, the dispensing of the filling material may start at a certain part of the surrounding clearance 5, which is in position corresponding to a certain region of the first substrate 600, and which is identified to be a certain degree away from a reference point.

Specifically, regarding factor (i), throughout each turn of rotation of the substrate holder 10 and the substrate assembly 50 disposed on the substrate holder 10, rotation speed thereof is controlled using the rotating controller 30, so as to control a speed of each of the different regions of the first substrate 600 that is swept over the dispenser valve 20. In some embodiments, the different regions of the first substrate 600 are respectively driven to sweep over the dispenser valve 20 at different speeds, while in other embodiments, each of the different regions of the first substrate 600 is driven to sweep over the dispenser valve 20 at a constant speed. A user can customize the speed(s) of each of the different regions of the first substrate 600 sweeping over the dispenser valve 20 according to practical needs, or condition (e.g., a length, a volume to be filled, or the like) of a corresponding one of the different parts of the surrounding clearance 5.

Regarding factor (ii), throughout each turn of rotation, as the different regions of the first substrate 600 are driven to sweep over the dispenser valve 20 at different on-off frequencies, the dispenser valve 20 thus dispenses different amounts of the filling material per degree of the perimeter path. In some embodiments, in each turn of rotation, the dispenser valve 20 is controlled to have different on-off frequencies when different regions (e.g., 61, 62) of the first substrate 600 are swept over the dispenser valve 20, and thus an amount of the filling material dispensed to the first part 51 per degree of the perimeter path can be different from an amount of the filling material dispensed to the second part 52 per degree of the perimeter path. In other embodiments, throughout each turn of rotation, the dispenser valve 20 is controlled to have a constant on-off frequency.

By varying the factors (i) and (ii), various dispensing modes can be employed to meet different requirements. Some of the dispensing modes in accordance with some embodiments are discussed below, but are not limited thereto.

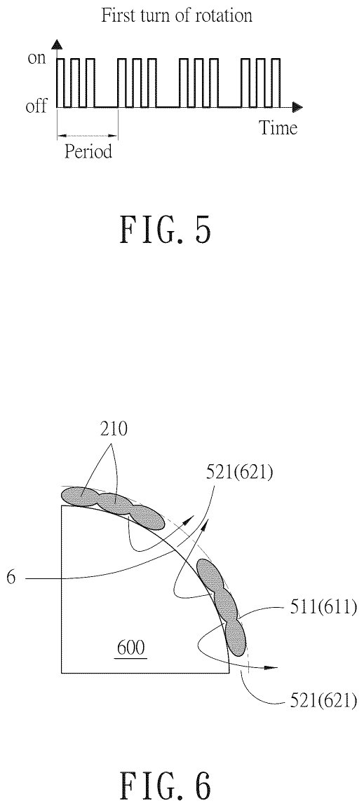

In accordance with some embodiments, the method of the present disclosure is performed in a periodic dispensing mode. FIG. 5 is a schematic plot showing an on-off status of the dispenser valve 20 versus time in the first turn of rotation in accordance with some embodiments (please note that only a portion of the first turn of rotation is shown in FIG. 5. The schematic plot shown in FIG. 5 is merely for illustrative purpose, and is not drawn to scale). Referring to FIGS. 4 and 5, in each period of dispensing for the first turn of rotation, one of the first sections 611 and a next one of the second sections 621 are sequentially swept through the dispense valve 20 at a first dispensed rate and a second dispensed rate, respectively. When each of the first sections 611 is swept through the dispense valve 20 at the first dispensed rate, a first amount of the filling material per degree of the perimeter path (e.g., three material portions 210 shown in FIG. 4) is dispensed to a corresponding one of the first areas 511. On the other hand, when each of the second sections 621 is swept through the dispense valve 20 at the second dispensed rate, a second amount of the filling material per degree of the perimeter path (e.g., no filling material) is dispensed to a corresponding one of the second areas 521. In this case, the first dispensed rate is greater than the second dispensed rate, and the first amount per degree of the perimeter path is greater than the second amount per degree of the perimeter path. Such dispense of the filling material along the dispensing clearance 5 is repeated at the first dispensed rate and the second dispensed rate for several times in each turn of rotation (therefore referred to as “a periodic dispensing mode”).

To achieve the embodiment shown in FIG. 4, exemplarily, when each of the first sections 611 is swept over the dispenser valve 20, the dispenser valve 20 is controlled at a first on-off frequency (e.g., the dispense valve 20 is switched on and off three times); and when each of the second sections 621 is swept over the dispenser valve 20, the dispenser valve 20 is controlled at a second on-off frequency (e.g., the dispense valve 20 remains switched off). The first on-off frequency is greater than the second on-off frequency. In addition, the substrate assembly 50 is rotated at a constant speed, i.e., each of the first sections 611 and each of the second sections 621 are swept over the dispenser valve 20 at the same speed. As such, the first dispensed rate and the first amount of the filling material per degree of the perimeter path relies on mainly the first on-off frequency; and the second dispensed rate and the second amount of the filling material per degree of the perimeter path relies on mainly the second on-off frequency. Please note that the amount of the filling material per degree of the perimeter path, and the on-off frequency may be varied according to practical needs.

FIG. 6 is a schematic fragmentary top view of the first substrate 600 showing gas release during merging and curing of the filling material in accordance with some embodiments. As the filling material is dispensed to the surrounding clearance 5, the adjacent material portions 210 merge and cure within a short period of time, (depending on the material, and/or operating condition of the dispensing of the filling material). The periodic dispensing mode allows the filling material to be dispensed merely to the first areas 511 of the surrounding clearance 5, and leaving the second areas 521 free of the filling material. This allows sufficient time and space for any gas, such as air, present within the first areas 511, to be expelled through the empty second areas 521 (see the arrows shown in FIG. 6) and not trapped between the filling material and the substrate assembly 50, before the filling material is cured. The voids that are trapped between the filling material and the substrate assembly 50 may undesirably cause damages, such as cracking of the first substrate 600, or the second substrate 700 in subsequent process (e.g., planarization of the first and/or second substrates 600, 700).

In the above description, the first amount of the filling material per degree of the perimeter path (or first dispensed rate) and the second amount of the filling material per degree of the perimeter path (or second dispensed rate) are controlled merely by varying the factor (ii), which is the on-off frequency of the dispenser valve 20. In other embodiments, the first amount of the filling material per degree of the perimeter path and the second amount of the filling material per degree of the perimeter path may also be varied by incorporating the factor (i), which is the speed of each of the different sections of the first substrate 600 that sweeps over the dispenser valve 20.

In accordance with some embodiments, when each of the first sections 611 of the first surrounding edge 6 is swept over the dispenser valve 20 at a first speed, and each of the second sections 621 of the first surrounding edge 6 is swept over the dispenser valve 20 at a second speed that is faster than the first speed (i.e., the factor (i) is varied), the first amount of the filling material per degree of the perimeter path on each of the first section 611 is greater than the second amount of the filling material per degree of the perimeter path on each of the second section 621. In certain embodiments, the on-off frequency of the dispenser valve 20 is kept constant throughout the entire turn of rotation of the substrate assembly 50. In such case, the first amount of the filling material per degree of the perimeter path (or the first dispensed rate) and the second amount of the filling material per degree of the perimeter path (or the second dispensed rate) merely depend on the factor (i), i.e., the first speed and the second speed, respectively. In other embodiments, in addition to varying the factor (i), the dispenser valve 20 is controlled at a first on-off frequency when each of the first sections 611 of the first surrounding edge 6 is swept over the dispenser valve 20, and is controlled at a second on-off frequency when each of the second sections 621 of the first surrounding edge 6 is swept over the dispenser valve 20. In such case, the first amount of the filling material per degree of the perimeter path (or the first dispensed rate) and the second amount of the filling material per degree of the perimeter path (or the second dispensed rate) depend on both the factors (i) and (ii). In order for the first amount of the filling material per degree of the perimeter path being greater than the second amount of the filling material per degree of the perimeter path, the first on-off frequency may be greater than the second on-off frequency.

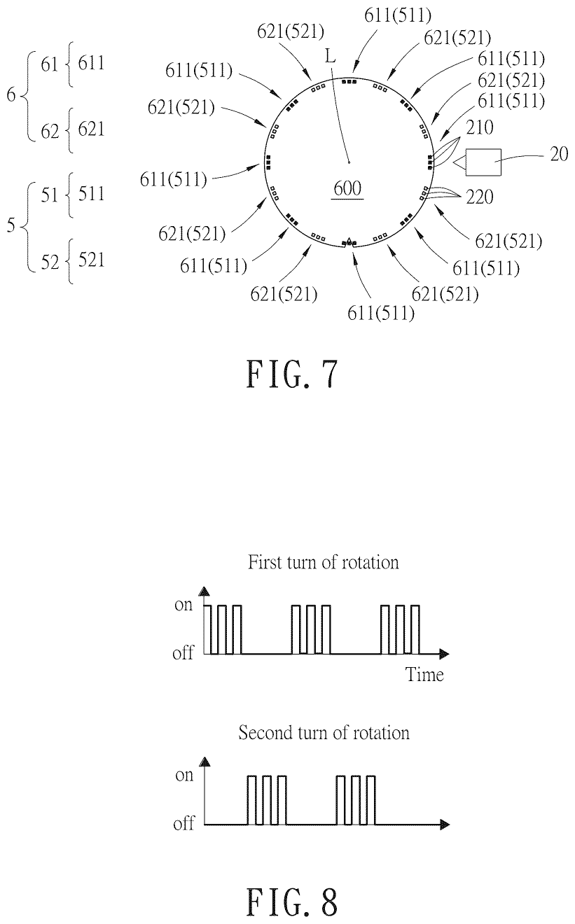

In FIGS. 4 to 6, the substrate assembly 50 is subjected to one turn of rotation (i.e., one cycle of the dispensing of the filling material), that merely the first part 51 (i.e., the first areas 511) of the surrounding clearance 5 is applied with the filling material, leaving the second part 52 (i.e., the second areas 521) of the surrounding clearance 5 empty. Whenever necessary, more turns of rotation of the substrate assembly 50 (i.e., more cycles of the dispensing of the filling material) may be performed, so as to apply more of the filling material to more different parts of the surrounding clearance 5. FIG. 7 is similar to FIG. 4 but illustrating the result after the second turn of rotation in accordance with some embodiments. FIG. 8 are schematic plots respectively showing on-off status of the dispenser valve 20 versus time in the first and second turns of rotation in accordance with some embodiments (please note that only portions of the first and second turns of rotation are shown. The schematic plots shown in FIG. 8 are merely for illustrative purpose, and are not drawn to scale) Referring to FIGS. 7 and 8, in each period of dispensing for the second turn of rotation, one of the first sections 611 and a next one of the second sections 621 are sequentially swept through the dispense valve 20 with a third dispensed rate and a fourth dispensed rate, respectively. When each of the first sections 611 is swept through the dispense valve 20 with the third dispensed rate, and thus a third amount of the filling material (e.g., no filling material) is dispensed. On the other hands, when each of the second sections 621 is swept through the dispense valve 20 with the fourth dispensed rate, and thus a fourth amount of the filling material (e.g., three material portions 220 shown in FIG. 7) is dispensed. In this case, the third dispensed rate is slower than the fourth dispensed rate, and the third amount per degree of the perimeter path is less than the fourth amount per degree of the perimeter path. In the second turn of rotation, the method is performed in another periodic dispensing mode variation. The filling material dispensed in the first turn of rotation may be the same as, or different form the filling material dispensed in the second turn of rotation, and may be determined according to practical needs. Please note that the material portions 210 dispensed in the first turn of rotation are indicated in darker shades, while the material portions 220 dispensed in the second turn of rotation are indicated in lighter shades, and the material portions 210, 220 in different shades are shown for illustrative purpose only.

To achieve the embodiment shown in FIG. 7, the first turn of rotation is similar to the description with reference to FIGS. 4 to 6. Referring to FIGS. 7 and 8, in the second turn of rotation, when each of the first sections 611 is swept over the dispenser valve 20, the dispenser valve 20 is controlled at a third on-off frequency (e.g., the dispense valve 20 is kept switched off) such that the third amount of the filling material per degree of the perimeter path is dispensed to a corresponding one of the first areas 511; and when each of the second sections 621 is swept over the dispenser valve 20, the dispenser valve 20 is controlled at a fourth on-off frequency (e.g., the dispense valve 20 is switched on and off three times) such that the fourth amount of the filling material per degree of the perimeter path is dispensed to a corresponding one of the second areas 521. In this case, the third on-off frequency is slower than the fourth on-off frequency, and the third amount of the filling material per degree of the perimeter path is less than the fourth amount of the filling material per degree of the perimeter path. Each of the first and second sections 611, 621 is swept over the dispenser valve 20 at a constant speed.

In this case shown in FIGS. 7 and 8, in the first turn of rotation, the filling material is dispensed to merely the first areas 511, and in the second turn of rotation, the filling material is dispensed to merely the second areas 521. As such, the filling material is dispensed to both the first areas 511 and the second areas 521 in turn. As such, the filling material is dispensed to and along the perimeter length of the surrounding clearance 5 but without undesirably trapping excessive amount of voids between the filling material and the substrate assembly 50. In this case, two turns of rotation are adopted, but are not limited thereto. There may be one, or two, or more turns of rotation according to practical needs.

The periodic dispensing mode may be adopted when the amount of the filling material dispensed along the perimeter length of the surrounding clearance 5 follows certain periodic pattern. For instance, in the case of FIGS. 4 and 5, three material portions 210 of the filling material are dispensed to each of the first areas 511, and none of the filling material dispensed to the second areas 521. Such pattern repeats, form a starting point of the rotation, along the perimeter length of the surrounding clearance 5 until the end of the rotation (by reaching the starting point). Correspondingly, the dispenser valve 20 has a first on-off frequency (i.e., the dispenser valve 20 is switched on and off three times when each of the first sections 611 is swept over the dispenser valve 20), and then a second on-off frequency (i.e., the dispenser valve 20 is kept switched off when each of the second sections 621 is swept over the dispenser valve 20), and such pattern is repeated from the starting point until the end of the rotation.

In accordance with some other embodiments, the method of the present disclosure is performed with a local dispensing mode, or may be known as a non-periodic dispensing mode. That is, throughout the entire turn of rotation, amounts of the filling material, or dispensed rates for each of the different parts of the surrounding clearance 51 are not fixed (and do not have a specific pattern) and rely on the volume of void of each of the different parts of the surrounding clearance 5 to be filled. This is especially beneficial in the case that the first and/or second substrates 600, 700 may accidentally have a peeling region, or may have intentionally formed patterns at the first and/or second surrounding edges 6, 7, and resulting in that different part(s) of the surrounding clearance 5 may have different volumes. Some parts of the surrounding clearance 5 may have a comparatively larger volume of void, while other parts of the surrounding clearance 5 may have a comparatively smaller volume of void. When one of the regions of the first substrate 600 is swept over the dispenser valve 20, in which a corresponding part of the surrounding clearance 5 has a comparatively larger volume of void than other parts of the surrounding clearance 5, (a) a corresponding dispensed rate is comparatively greater, and (b) a corresponding amount of the filling material dispensed to the corresponding part of the surrounding clearance 5 per degree of the perimeter path is comparatively greater. That is, a comparatively greater amount of the filling material is dispensed to the corresponding part of the surrounding clearance 5 than the other parts of the surrounding clearance 5.

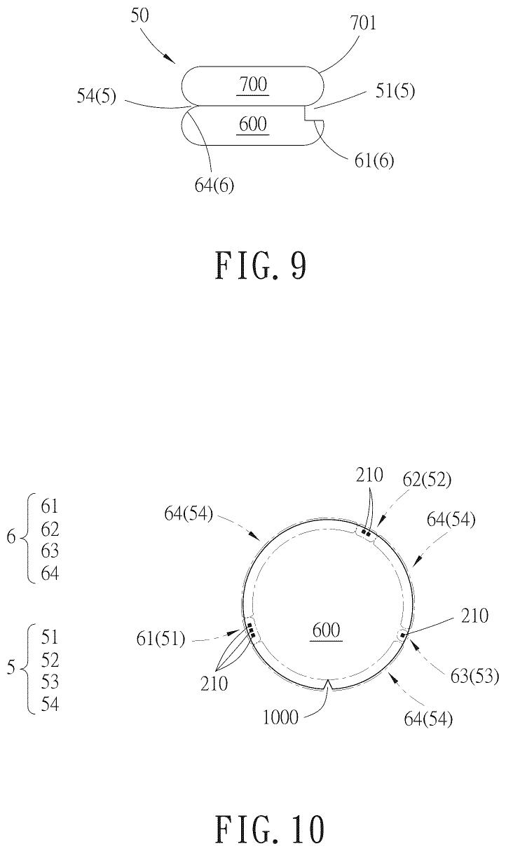

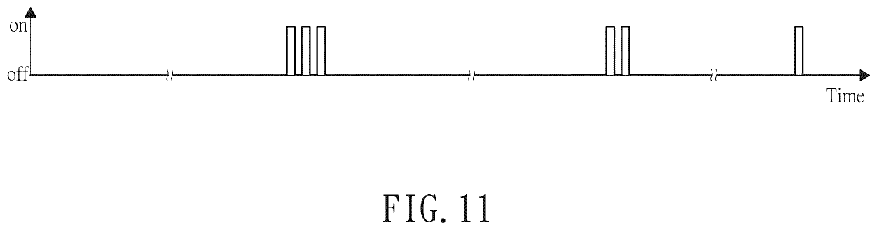

FIG. 9 is a schematic cross sectional view of a substrate assembly 50 in accordance with some embodiments. FIG. 10 is a top view of FIG. 9 but omitting the second substrate 700 in accordance with some embodiments. The substrate assembly 50 shown in FIGS. 9 and 10 is similar to that shown in FIGS. 1 and 2 but the first substrate 600 has some peeling regions. Referring to FIGS. 9 and 10, the first surrounding edge 6 of the first substrate 600 has a first region 61 (located in a first part 51 of the surrounding clearance 5), a second region 62 (located in a second part 52 of the surrounding clearance 5), a third region 63 (located in a third part 53 of the surrounding clearance 5), and three fourth regions 64 (located respectively in three fourth parts 54 of the surrounding clearance 5). The first, second and third regions 61, 62, 63 are peeling regions with different extent of peeling. Degree of peeling is the most severe at the first region 61, and less severe in the second region 62, and least severe in the third region 63. No peeling is observed in the three fourth regions 64. Therefore, the first part 51 that is bordered by the first region 61 with the most severe peeling has a comparatively large volume of void; while each of the fourth parts 54 that is bordered by a corresponding one of the fourth regions 64 with no peeling has a comparatively small volume of void. As shown in FIG. 10, correspondingly, a comparatively greater amount of filling material, i.e., three material portions 210, are dispensed to the first part 51 that has the largest volume of void, while no filling material is dispensed to the fourth parts 54 that has the smallest volume of void. FIG. 11 is a schematic plot showing an on-off status of the dispenser valve 20 from beginning of dispensing to the end of dispensing (The schematic plot shown in FIG. 11 is merely for illustrative purpose, and is not drawn to scale). In this case, the dispensing of the filling material begins at the first region 61. When the first region 61 is swept over the dispenser valve 20, the dispenser valve 20 is driven to switch between on and off status three times (see FIG. 11) to dispense the three material portions 210 in the first part 51 (see FIG. 10). When each of the fourth regions 64 is swept over the dispenser valve 20, the dispenser valve 20 remains at off status to leave each fourth part 514 empty. When the second region 62 is swept over the dispenser valve 20, the dispenser valve 20 is driven to switch between on and off status twice to dispense two material portions 210 to the second part 52 having a smaller volume of void than that of the first part 51. When the third region 63 is swept over the dispenser valve 20, the dispenser valve 20 is driven to switch between on and off status once to dispense one material portion 210 to the third part 53 having an even smaller volume of void than that of the second part 52.

As shown in FIG. 11, the aforementioned factor (ii), the dispenser valve 20 may be controlled to have an unfixed on-off frequency throughout the turn of rotation. In other embodiments, the factor (i), i.e, speeds of different regions of the first substrate 600 that are swept over the dispenser valve 20 may also be varied. The combination of the factors (i) and (ii) may customize and vary amount of the filling material that is dispensed to different parts of the surrounding clearance 5 with different volumes of void, so as to ensure that the customized amount of the filling material offers sufficient supports to the first and/or second substrates 600, 700.

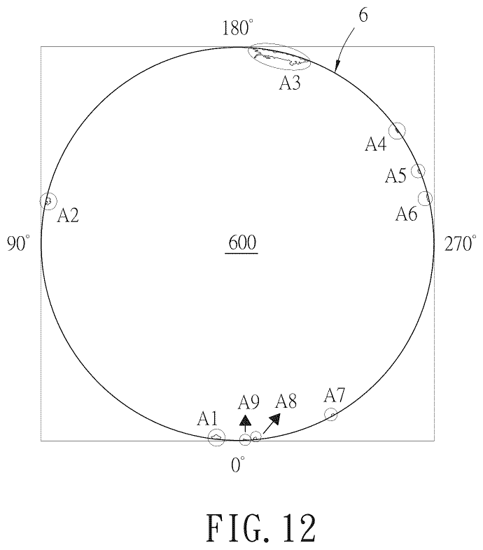

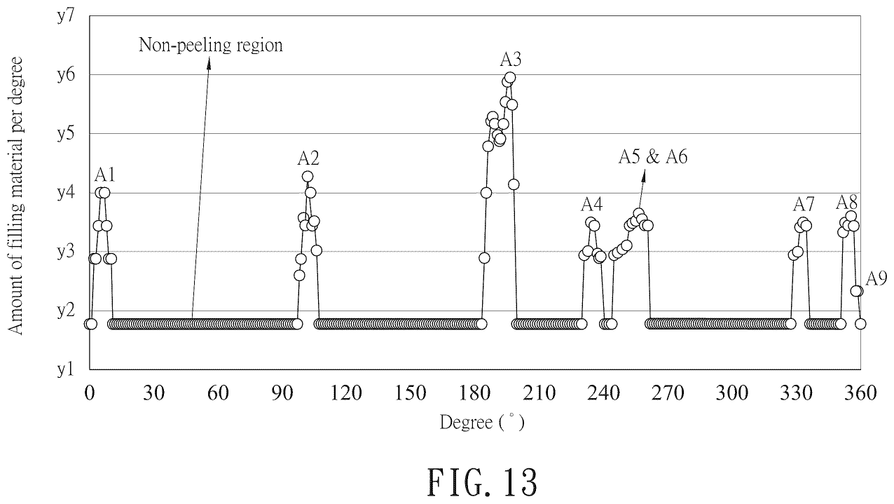

FIGS. 12 and 13 each illustrates another example of the filling material being dispensed in the non-periodic dispensing mode. FIG. 12 shows a schematic top view of the first substrate 600 with nine peeling regions, namely A1, A2, A3, A4, A5, A6, A7, A8, and A9 at the surrounding edge 6, and remaining regions of the surrounding edge 6 are known as the non-peeling regions. A9 is located at 0°, which marks the starting point and end point of the turn of rotation. FIG. 13 is a plot showing an amount of the filling material dispensed to the surrounding clearance 5 per degree of the perimeter path with reference to a starting point of 0° in accordance with some embodiments. As shown in FIG. 13, Y-axis represents an amount of the filling material dispensed to the surrounding clearance 5 per degree of the perimeter path (which is proportional to a dispensed rate), wherein 0<y1<y2<y3<y4<y5<y6<y7, whereas X-axis represents a degree of the perimeter length relative to the starting point of 0°. It can be seen that when those non-peeling regions are swept over the dispenser valve 20, the dispensed amounts per degree thereof are relatively lower, i.e., less than approximately y2, and kept constant. In contrast, when the nine peeling regions are swept over the dispenser valve 20, the dispensed amounts per degree thereof are relatively higher. In each of the peeling regions, the dispensed amounts per degree are not constant throughout the peeling regions and may be varied according to the extent of peeling.

Referring to FIG. 3, the method proceeds to step 103, where a heating treatment is performed on the filling material in the surrounding clearance 5 (see FIG. 1), so that the filling material cures. Any suitable heating treatment and conditions known in the art may be adopted, such that the cured filling material provides enough support to the first and/or second substrates 600, 700 to any subsequent processes.

In some embodiments, the step 102 and step 103 are each performed once. That is, after finishing dispensing the filling material into all parts of the surrounding clearance 5, the heating treatment is performed to cure the filling material in the surrounding clearance 5. For instance, as mentioned in FIGS. 7 to 8, when more than one turn of rotation is required, after finishing the first turn of rotation for dispensing the filling material into each of the first areas 511 and the second turn of rotation for dispensing the filling material into each of the second areas 521, the heating treatment is performed to cure the filling material in each of the first and second areas 511, 521.

In other embodiments, the step 102 and step 103 are repeated. For instance, after a certain amount of the filling material is dispensed to the surrounding clearance 5 (step 102), a heating treatment is first performed (step 103), then continue dispensing another amount of the filling material to the surrounding clearance 5 (repeating step 102), then performing another heating treatment (repeating step 103). Continue using the example discussed in FIGS. 7 to 8, after the first turn of rotation, in which the filling material is dispensed into the first areas 511, a first heating treatment may be immediately performed before the second turn of rotation. Then the second turn of rotation follows to dispense the filling material into the second areas 521, and a second heating treatment may be immediately performed.

Referring to FIG. 3, the method proceeds to step 104, where a planarization process is performed.

Any suitable planarization process known in the art may be employed. Example of the planarization process is a chemical-mechanical polishing (CMP) process, but is not limited thereto. The planarization process is performed on a surface of the second substrate 700 of the substrate assembly 50 opposite to the first substrate 600. Step 104 may be known as a thinning down process to remove a majority of the second substrate 700, until a total thickness of the substrate assembly 50 is reduced to nearly a thickness of the first substrate 600, such that the resultant substrate assembly 50 has a relatively thin thickness.

By completing step 104, the method for treating the first and second substrates 600, 700 is considered completed. After step 104, as an upper portion of the second substrate 700 is removed, a periphery of the filling material may be exposed from the second substrate 700. It is observed, comparing with filling material of a substrate assembly that is not prepared according to the present disclosure (i.e., the filling material in different parts of the surrounding clearance cannot be varied), the substrate assembly 50 of the present disclosure has greatly reduced amount of voids within the filling material, and thus cracking of the filling material is also greatly reduced. In addition, in the case that the first substrate 600 having peeling regions, resulting in irregular volume of parts of the surrounding clearance 5 along the first and second surrounding edges 6, 7, the method of the present disclosure is capable to vary and customize the amount of the filling material into different parts of the surrounding clearance 5, so that the first and second surrounding edges 6, 7 are well supported by the filling materials, i.e., there is rarely hanging portions of the first and second surrounding edges 6, 7.

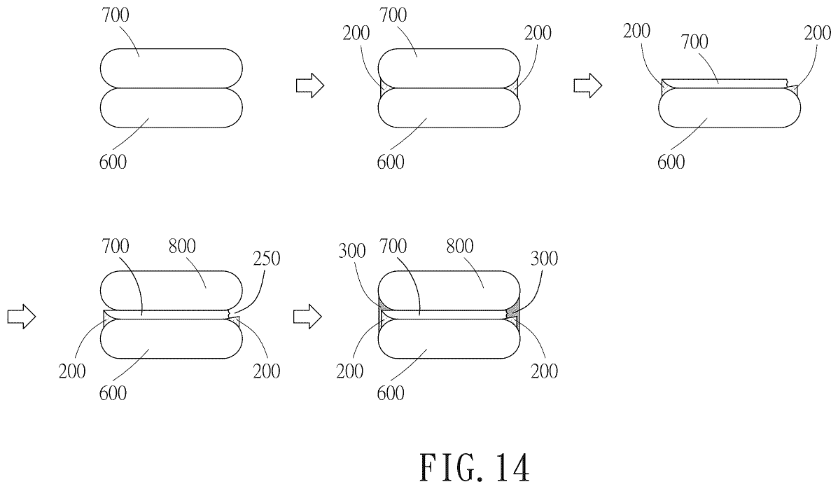

In accordance with other examples, the method of the present disclosure may be repeated in the case of multi-wafer bonding. FIG. 14 is a schematic process flow diagram illustrating bonding of multiple wafers in accordance with some embodiments.

Referring to FIG. 14, the upper row shows intermediate steps of a first bonding process to bond the first and second substrates 600, 700 using the method according to the present disclosure, i.e., by first bonding the first substrate 600 and the second substrate 700 together (step 101 of the method as discussed), followed by applying a first filling material 200 to a clearance between the first and second substrates 600, 700 together (steps 102 and 103 of the method as discussed), and followed by thinning down the second substrate 700 (step 104 of the method as discussed). During the thinning down process, in some cases, a minor amount of cracking might still be accidentally induced. For instance, in the first bonding process, as shown in the rightmost part of the upper row, the first filling material 200 at left side remains intact, while a piece of the first filling material 200 at the right side is missing, and results in a void 250.

Referring again to FIG. 14, the lower row shows some of the intermediate steps of a second bonding process to bond a third substrate 800 to the second substrate 700 using the method according to the present disclosure. In the lower row, the left part of the figure shows bonding of the third substrate 800 onto an upper surface of the thinned-down second substrate 700 (step 101 of the method as discussed), followed by, applying a second filling material 300 to a clearance between the first, the second and the third substrates 600, 700, 800 (steps 102, 103 of the method as discussed, structure obtained after step 104 in the second bonding process is not shown in FIG. 14). By using the method of the present disclosure, the amount of the second filling material 300 applied to the left side and the right side of the clearance between the first, the second and the third substrates 600, 700, 800 can be customized. In addition, the second filling material 300 can be easily filled in the void 250, and thus provides enough support to the substrates 600, 700, 800. In the exemplary embodiment, two wafer bonding processes are demonstrated to bond three substrates together, though in other embodiments, more wafer bonding processes may be employed whenever necessary, to bond a greater number of substrates together.

The embodiments of the present disclosure have the following advantageous features. By varying speed of regions of the first substrates swept over the dispenser valve 20, and/or by varying on-off frequency of the dispenser valve 20, amounts of the filling material dispensed to the different parts of the surrounding clearance 5 may be customized. The method of the present disclosure permits periodic dispensing mode, such that there is sufficient time and space for gas to be released before curing of the filling material, thereby greatly reducing amount of voids in the surrounding clearance 5. In addition, the method of the present disclosure permits local dispensing mode, such that different parts of the surrounding clearance 5 having different volumes may be filled with different amounts of the filling material, respectively, thereby providing enough support to the first and second substrates 600, 700.

In accordance with some embodiments of the present disclosure, a method for treating a first substrate and a second substrate includes: bonding a first substrate with a second substrate to obtain a substrate assembly with a surrounding clearance between a first surrounding edge of the first substrate and a second surrounding edge of the second substrate, the first surrounding edge having a first region and a second region which are located in a first part and a second part of the surrounding clearance, respectively; and rotating the substrate assembly while dispensing a filling material to the surrounding clearance, in a first turn of rotation of the substrate assembly, the filling material being dispensed to the first part and the second part at a first dispensed rate and a second dispensed rate, respectively, the first dispensed rate being greater than the second dispensed rate.

In accordance with some embodiments of the present disclosure, the substrate assembly is disposed on and rotated by a substrate holder, and a dispenser valve is disposed aside the substrate holder to dispense the filling material to the surrounding clearance.

In accordance with some embodiments of the present disclosure, in the first turn of rotation of the substrate assembly, the first region of the first surrounding edge is swept over the dispenser valve at a first speed, and the second region of the first surrounding edge is swept over the dispenser valve at a second speed that is faster than the first speed.

In accordance with some embodiments of the present disclosure, in the first turn of rotation of the substrate assembly, an on-off frequency of the dispenser valve is kept constant.

In accordance with some embodiments of the present disclosure, in the first turn of rotation of the substrate assembly, the dispenser valve is controlled at a first on-off frequency when the first region of the first surrounding edge is swept over the dispenser valve, and is controlled at a second on-off frequency when the second region of the first surrounding edge is swept over the dispenser valve, the first on-off frequency being greater than the second on-off frequency.

In accordance with some embodiments of the present disclosure, in the first turn of rotation of the substrate assembly, the dispenser valve is controlled at a first on-off frequency when the first region of the first surrounding edge is swept over the dispenser valve, and is controlled at a second on-off frequency when the second region of the first surrounding edge is swept over the dispenser valve, the first on-off frequency being greater than the second on-off frequency.

In accordance with some embodiments of the present disclosure, in the first turn of rotation of the substrate assembly, the substrate assembly is rotated at a constant speed.

In accordance with some embodiments of the present disclosure, the method further includes performing a heating treatment on the filling material in the surrounding clearance; and after the heating treatment, performing a planarization process on a surface of the second substrate of the substrate assembly opposite to the first substrate.

In accordance with some embodiments of the present disclosure, in the first turn of rotation of the substrate assembly, the second dispensed rate is zero.

In accordance with some embodiments of the present disclosure, in a second turn of rotation of the substrate assembly, the filling material is dispensed in the first part at a third dispensed rate, and the filling material is dispensed in the second part at a fourth dispensed rate, the third dispensed rate being less than the fourth dispensed rate.

In accordance with some embodiments of the present disclosure, in the second turn of rotation of the substrate assembly, the third dispensed rate is zero.

In accordance with some embodiments of the present disclosure, the first region has first sections which are angularly displaced from each other, and the second region has second sections which are angularly displaced from each other such that the second sections angularly alternate with the first sections.

In accordance with some embodiments of the present disclosure, a method for treating a first substrate and a second substrate includes: bonding the first substrate with the second substrate to obtain a substrate assembly with a surrounding clearance between a first surrounding edge of the first substrate and a second surrounding edge of the second substrate, the first surrounding edge having a first region and a second region which are angularly displaced from each other and which are respectively located in a first part and a second part of the surrounding clearance; and rotating the substrate assembly around an axis while dispensing a filling material to the surrounding clearance along a perimeter path around the axis in a manner that in one turn of rotation of the substrate assembly, an amount of the filling material dispensed to the first part per degree of the perimeter path is greater than an amount of the filling material dispensed to the second part per degree of the perimeter path.

In accordance with some embodiments of the present disclosure, the substrate assembly is disposed on and rotated by a substrate holder, and a dispenser valve is disposed aside the substrate holder to dispense the filling material to the surrounding clearance.

In accordance with some embodiments of the present disclosure, in the one turn of rotation of the substrate assembly, the first region of the first surrounding edge is swept over the dispenser valve at a first speed, and the second region of the first surrounding edge is swept over the dispenser valve at a second speed that is faster than the first speed.

In accordance with some embodiments of the present disclosure, in the one turn of rotation of the substrate assembly, the dispenser valve is controlled at a first on-off frequency when the first region of the first surrounding edge is swept over the dispenser valve, and is controlled at a second on-off frequency when the second region of the first surrounding edge is swept over the dispenser valve, the first on-off frequency being greater than the second on-off frequency.

In accordance with some embodiments of the present disclosure, the method further includes performing a heating treatment on the filling material in the surrounding clearance after the one turn of rotation of the substrate assembly.

In accordance with some embodiments of the present disclosure, a volume of the first part is larger than a volume of the second part.

In accordance with some embodiments of the present disclosure, a semiconductor apparatus includes a substrate holder, a rotating controller and a dispenser valve. The substrate holder is for retaining a substrate assembly thereon. The substrate assembly has a first substrate and a second substrate, and is formed with a surrounding clearance between the first substrate and the second substrate. The rotating controller is coupled to the substrate holder to control rotation speed of the substrate holder. The dispenser valve is disposed aside the substrate holder to dispense a filling material to the surrounding clearance.

In accordance with some embodiments of the present disclosure, the semiconductor apparatus includes a dispensing controller coupled to the dispenser valve to control an on-off frequency of the dispenser valve.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for treating a first substrate and a second substrate, comprising:
bonding a first substrate with a second substrate to obtain a substrate assembly with a surrounding clearance between a first surrounding edge of the first substrate and a second surrounding edge of the second substrate, the first surrounding edge having a first region and a second region which are located in a first part and a second part of the surrounding clearance, respectively; and
rotating the substrate assembly while dispensing a filling material to the surrounding clearance,
in a first turn of rotation of the substrate assembly, the filling material being dispensed to the first part and the second part at a first dispensed rate and a second dispensed rate, respectively, the first dispensed rate being greater than the second dispensed rate.

2. The method according to claim 1, wherein the substrate assembly is disposed on and rotated by a substrate holder, and a dispenser valve is disposed aside the substrate holder to dispense the filling material to the surrounding clearance.

3. The method according to claim 2, wherein, in the first turn of rotation of the substrate assembly, the first region of the first surrounding edge is swept over the dispenser valve at a first speed, and the second region of the first surrounding edge is swept over the dispenser valve at a second speed that is faster than the first speed.

4. The method according to claim 3, wherein, in the first turn of rotation of the substrate assembly, an on-off frequency of the dispenser valve is kept constant.

5. The method according to claim 3, wherein, in the first turn of rotation of the substrate assembly, the dispenser valve is controlled at a first on-off frequency when the first region of the first surrounding edge is swept over the dispenser valve, and is controlled at a second on-off frequency when the second region of the first surrounding edge is swept over the dispenser valve, the first on-off frequency being greater than the second on-off frequency.

6. The method according to claim 2, wherein, in the first turn of rotation of the substrate assembly, the dispenser valve is controlled at a first on-off frequency when the first region of the first surrounding edge is swept over the dispenser valve, and is controlled at a second on-off frequency when the second region of the first surrounding edge is swept over the dispenser valve, the first on-off frequency being greater than the second on-off frequency.

7. The method according to claim 6, wherein in the first turn of rotation of the substrate assembly, the substrate assembly is rotated at a constant speed.

8. The method according to claim 1, further comprising:
performing a heating treatment on the filling material in the surrounding clearance; and
after the heating treatment, performing a planarization process on a surface of the second substrate of the substrate assembly opposite to the first substrate.

9. The method according to claim 1, wherein, in the first turn of rotation of the substrate assembly, the second dispensed rate is zero.

10. The method according to claim 1, wherein, in a second turn of rotation of the substrate assembly, the filling material is dispensed in the first part at a third dispensed rate, and the filling material is dispensed in the second part at a fourth dispensed rate, the third dispensed rate being less than the fourth dispensed rate.

11. The method according to claim 10, wherein, in the second turn of rotation of the substrate assembly, the third dispensed rate is zero.

12. The method according to claim 1, wherein
the first region has first sections which are angularly displaced from each other, and
the second region has second sections which are angularly displaced from each other such that the second sections angularly alternate with the first sections.

13. A method for treating a first substrate and a second substrate, comprising:
bonding the first substrate with the second substrate to obtain a substrate assembly with a surrounding clearance between a first surrounding edge of the first substrate and a second surrounding edge of the second substrate, the first surrounding edge having a first region and a second region which are angularly displaced from each other and which are respectively located in a first part and a second part of the surrounding clearance; and
rotating the substrate assembly around an axis while dispensing a filling material to the surrounding clearance along a perimeter path around the axis in a manner that in one turn of rotation of the substrate assembly, an amount of the filling material dispensed to the first part per degree of the perimeter path is greater than an amount of the filling material dispensed to the second part per degree of the perimeter path.

14. The method according to claim 1, wherein the substrate assembly is disposed on and rotated by a substrate holder, and a dispenser valve is disposed aside the substrate holder to dispense the filling material to the surrounding clearance.

15. The method according to claim 14, wherein, in the one turn of rotation of the substrate assembly, the first region of the first surrounding edge is swept over the dispenser valve at a first speed, and the second region of the first surrounding edge is swept over the dispenser valve at a second speed that is faster than the first speed.

16. The method according to claim 14, wherein, in the one turn of rotation of the substrate assembly, the dispenser valve is controlled at a first on-off frequency when the first region of the first surrounding edge is swept over the dispenser valve, and is controlled at a second on-off frequency when the second region of the first surrounding edge is swept over the dispenser valve, the first on-off frequency being greater than the second on-off frequency.

17. The method according to claim 13, further comprising performing a heating treatment on the filling material in the surrounding clearance after the one turn of rotation of the substrate assembly.

18. The method according to claim 13, wherein a volume of the first part is larger than a volume of the second part.

19. A semiconductor apparatus, comprising:
a substrate holder for retaining a substrate assembly thereon, the substrate assembly having a first substrate and a second substrate, and being formed with a surrounding clearance between the first substrate and the second substrate;
a rotating controller coupled to the substrate holder to control rotation speed of the substrate holder; and
a dispenser valve disposed aside the substrate holder to dispense a filling material to the surrounding clearance.

20. The semiconductor apparatus according to claim 19, further comprising:
a dispensing controller coupled to the dispenser valve to control an on-off frequency of the dispenser valve.
